(19) United States
(12) Patent Application Publication
(10) Pub. No.: US 2005/0007176 A1
(43) Pub. Date: Jan. 13, 2005

(54) Semiconductor integrated circuit

(76) Inventor: Hiroshi Seki, Suwa-shi (JP)

Correspondence Address: HARNESS, DICKEY & PIERCE, P.L.C., P.O. BOX 828, BLOOMFIELD HILLS, MI, 48303, US

(21) Appl. No.: 10/861,230

(22) Filed: Jun. 3, 2004

(30) Foreign Application Priority Data
Jun. 4, 2003 (JP) 2003-158813

(51) Int. Cl. H03L 7/00

(52) U.S. Cl. 327/333

(57) ABSTRACT

A semiconductor integrated circuit is provided that operates with a first power supply voltage and a second power supply voltage that is higher than the first power supply voltage. The circuit comprises at least one transistor that drops the second power supply voltage, a first-stage level shifter operated with a voltage supplied from the second power supply voltage via at least one transistor and shifting a level of a signal input from a circuit that is operated with the first power supply voltage, and a second-stage level shifter operated with the second power supply voltage and shifting a level of a signal input from at least one level shifter.

### RELATED APPLICATIONS

This applications claims priority to Japanese Patent Application No. 2003-158813 filed Jun. 4, 2003 which is hereby expressly incorporated by reference herein in its entirety.

### BACKGROUND

1. Field of the Invention

This invention generally relates to semiconductor integrated circuits such as an IC and an LSI, and specifically relates to semiconductor integrated circuits that are operated with multiple power supply voltages.

2. Description of the Related Art

In recent years, to operate various electronic devices at high speed and with low power consumption, highly-integrated and low-voltage semiconductor integrated circuits such as an IC and LSI used for these electronic devices are being developed. However, in consideration of the unique characteristics of electronic devices, it is very difficult to lower the operation voltage of all semiconductor integrated circuits uniformly. Consequently, a plurality of semiconductor integrated circuits operated with different power supply voltages may be connected to each other.

To handle such a situation, a semiconductor integrated circuit incorporating a level-shift circuit that enhances the level of a signal output from a circuit operated with a low power supply voltage so as to supply the signal to a circuit operated with a high power supply voltage, has been developed. FIG. 3 illustrates an example of a level-shift circuit used in a conventional semiconductor integrated circuit.

A level-shift circuit (level shifter) shown in FIG. 3 comprises a first inverter that is made up of a P-channel MOS transistor QP11 and an N-channel MOS transistor QN11, and a second inverter that is made up of a P-channel MOS transistor QP12 and an N-channel MOS transistor QN12. The level-shift circuit also comprises a P-channel MOS transistor QP13 that is coupled to power supply voltage HV_{DD} and the first inverter, and a P-channel MOS transistor QP14 that is coupled to the power supply voltage HV_{DD} and the second inverter. An output signal from the second inverter is supplied to a gate of the transistor QP13, and an output signal from the first inverter is supplied to a gate of the transistor QP14.

An inverter 10 operated by the provision of power supply voltage LV_{DD}, is provided between the inputs of the first and second inverters. Meanwhile, the power supply voltage HV_{DD} is supplied to the sources of the transistors QP13 and QP14. Consequently, a signal at a level of 0 through LV_{DD} input to the level shifter is output as a signal at a level of 0 through HV_{DD}.

However, if the power supply voltage LV_{DD} is lowered, and a difference between the power supply voltages LV_{DD} and HV_{DD} gets larger, a level shifter may function abnormally. In general, when the power supply voltage LV_{DD} becomes lower to the extent that the formula “LV_{DD} <HV_{DD}/3” is satisfied, a level shifter usually functions abnormally. For example, when the power supply voltage HV_{DD} is 3.6V, if the power supply voltage LV_{DD} is lower than 1.2V, a level shifter functions abnormally.

A level converter that can improve an operation minimum (a circuit performance) of a level conversion operation is disclosed in Japanese Unexamined Patent Application Publication 2002-204153 (Page 1, FIG. 1). In this level converter, more than three level shifters are cascade-connected. The first-stage level shifter converts an input signal to a voltage between VH-V_{SS}, and then the second-stage level shifter converts the voltage between VH-V_{SS} to voltage VH-VL1, and thereafter the third-stage level shifter converts the voltage between VH-VL1 to voltage VH-VL2. The relationship between the voltages is indicated as “VH>V_{SS}>VL1>VL2”. As a result, the breakdown voltage between each level shifter can be maintained in a certain range and the difference of converted electric potential between each level shifter can be minimized. Hence, the performance of the conversion operation can be enhanced.

By connecting each of many level shifters to one of many different power supply voltages uniquely, this level converter can shift the signal level stepwise. However, to generate many different power supply voltages, many power supply circuits are also needed. Therefore, it is desired to establish a level-shift circuit enabling the same operation with only two power supply voltages of input and output.

In view of the above problem, the present invention is intended to provide a semiconductor integrated circuit that can be operated with only two power supply voltages and incorporates a level-shift circuit having superior level shift ability.

### SUMMARY

In order to solve the above problems, a semiconductor integrated circuit according to the present invention operated by the provision of a first power supply voltage and a second power supply voltage that is higher than the first power supply voltage comprises at least one transistor that drops the second power supply voltage, and at least one level shifter operated with the voltage supplied from the second power supply voltage via the at least one transistor, and shifting a level of a signal input from a circuit that is operated with the first power supply voltage. The semiconductor integrated circuit also comprises a last-stage level shifter operated with the second power supply voltage and shifting a level of a signal that is input from the at least one level shifter.

In the semiconductor integrated circuit, the at least one transistor may comprise a saturated-connected N-channel MOS transistor. Furthermore, threshold voltage of the at least one transistor may be higher than threshold voltage of other transistors. In addition, the at least one level shifter may comprise an i-th-stage level shifter (i=1, 2, . . . through M. M is a counting number) that is operated with voltage supplied from the second power supply voltage via Nᵢ transistors, and the following relationship may be satisfied:
N₁>N₂> . . . >N_{M}.

In the above semiconductor integrated circuit, a first-stage level shifter of the at least one level shifter may comprise an input inverter operated with the first power supply voltage and inverting a signal input from a circuit that is operated with the first power supply voltage, a first inverter comprising a P-channel MOS transistor and an N-channel MOS transistor and inverting a signal input from a circuit that is operated with the first power supply voltage so as to produce a first output signal, and a second inverter comprising a P-channel MOS transistor and an N-channel MOS transistor and inverting a signal output from the input inverter so as to produce a second output signal. The first-stage level shifter may also comprise a P-channel MOS transistor connected to the at least one transistor and the P-channel MOS transistor of the first inverter, and whose gate receives the second output signal, and a P-channel MOS transistor connected to the at least one transistor and the P-channel MOS transistor of the second inverter, and whose gate receives the first output signal.

In addition, the second-stage and subsequent-stage level shifters or the last-stage level shifter, of the at least one level shifter may comprise a first inverter comprising a P-channel MOS transistor and an N-channel MOS transistor and inverting one of the output signals from a previous-stage level shifter so as to produce a first output signal, and a second inverter comprising a P-channel MOS transistor and an N-channel MOS transistor and inverting the other of the output signals from the previous-stage level shifter so as to produce a second output signal. The second-stage and subsequent-stage level shifters or the last-stage level shifter may also comprise a P-channel MOS transistor connected to the at least one transistor and the P-channel MOS transistor of the first inverter, and whose gate receives the second output signal, and a P-channel MOS transistor connected to the at least one transistor and the P-channel MOS transistor of the second inverter, and whose gate receives the first output signal.

According to the above structure of the invention, at least one level shifter operated with the voltage supplied from the second power supply voltage via at least one transistor, and the last-stage level shifter operated with the second power supply voltage, are provided, such that a semiconductor integrated circuit that can be operated with only two power supply voltages and incorporates a level shifter having a superior level shift ability can be provided.

### BRIEF DESCRIPTION OF THE DRAWINGS

FIG. 1 is a diagram showing a level-shift circuit of a first embodiment of the present invention.

FIG. 2 is a diagram showing a level-shift circuit of a second embodiment of the present invention.

FIG. 3 is a diagram showing an example of a level-shift circuit of a conventional semiconductor integrated circuit.

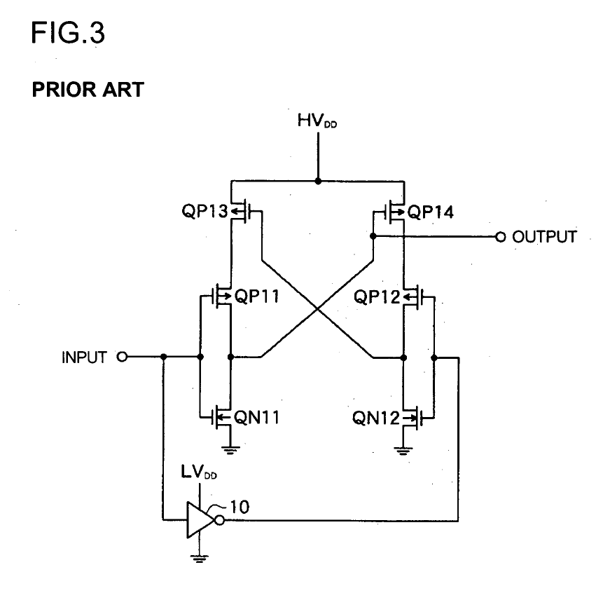

### DETAILED DESCRIPTION

Embodiments of the present invention will be described in detail below reference to drawings. Identical reference numerals designate identical elements, and duplicate explanations thereof will be omitted.

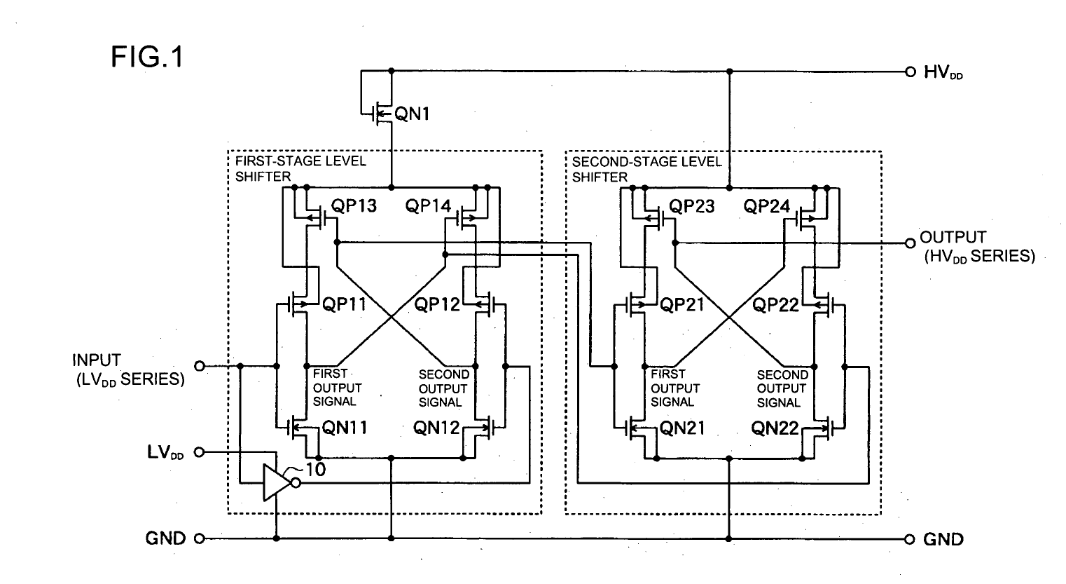

FIG. 1 is a schematic diagram showing a structure of a level-shift circuit included in a semiconductor integrated circuit according to a first embodiment of the invention. This semiconductor integrated circuit is operated by the provision of first power supply voltage LV_{DD} and second power supply voltage HV_{DD} that is higher than the first one (3.6 V in the embodiment).

As shown in FIG. 1, this level-shift circuit comprises at least one transistor that drops the second power supply voltage HV_{DD} (an N-channel MOS transistor QN1 in FIG. 1), a first-stage level shifter that is operated with the voltage supplied from the second power supply voltage HV_{DD} via the transistor QN1 and shifts the level of a signal input from a circuit operated with the first power supply voltage LV_{DD}, and a second-stage level shifter that is operated with the second power supply voltage HV_{DD} and shifts the level of a signal input from the first-stage level shifter.

The transistor QN1 is saturated-connected so as to cause a voltage drop equal to the threshold voltage V_{THN} of the transistor QN1 (0.6V in the embodiment) between the drain and source thereof. The threshold voltage V_{THN} of the transistor QN1 may be larger than that of another N-channel MOS transistors and P-channel MOS transistors.

The first-stage level shifter comprises the input inverter 10 that operates with the first power supply voltage LV_{DD}, a first inverter that comprises the P-channel MOS transistor QP11 and the N-channel MOS transistor QN11, and a second inverter that comprises the P-channel MOS transistor QP12 and the N-channel MOS transistor QN12. The first-stage level shifter also comprises the P-channel MOS transistor QP13 that is coupled to the transistor QN1 and the transistor QP11, and the P-channel MOS transistor QP14 that is coupled to the transistor QN1 and the transistor QP12.

In the first-stage level shifter, the input inverter 10 inverts an input signal input from a circuit operated with the first power supply voltage LV_{DD}. The first inverter produces a first output signal by inverting an input signal input from a circuit operated with the first power supply voltage LV_{DD}. Meanwhile, the second inverter produces a second output signal by inverting the signal output from the input inverter 10. The first output signal is applied to a gate of the transistor QP14, and the second output signal is applied to a gate of the transistor QP13.

The second-stage level shifter comprises a first inverter that comprises a P-channel MOS transistor QP21 and an N-channel MOS transistor QN21, and a second inverter that comprises a P-channel MOS transistor QP22 and an N-channel MOS transistor QN22. The second-stage level shifter also comprises a P-channel MOS transistor QP23 that is coupled to the second power supply voltage HV_{DD} and the transistor QP21, and a P-channel MOS transistor QP24 that is coupled to the second power supply voltage HV_{DD} and the transistor QP22.

In the second-stage level shifter, the first inverter produces a first output signal by inverting the second output signal from the first-stage level shifter. The second inverter produces a second output signal by inverting the first output signal from the first-stage level shifter. The first output signal from the second-stage level shifter is applied to a gate of the transistor QP24, and the second output signal from the second-stage level shifter is applied to a gate of the transistor QP23. In the embodiment, the second output signal from the second-stage level shifter is output as an output signal of the level-shift circuit.

Here, the voltage yielded by subtracting the voltage V_{THN}, which corresponds to the voltage drop at the transistor QN1, from the second power supply voltage HV_{DD}, is applied to the sources of the transistors QP13 and QP14 of the first-stage level shifter. Generally, if it is assumed that a level shifter will function abnormally when the first power supply voltage LV_{DD} satisfies LV_{DD}<HV_{DD}/3, in consideration of the amount of voltage drop N·V_{THN} caused by N transistors for dropping the second power supply voltage HV_{DD}, the range of the power supply voltage LV_{DD} in which the first stage level shifter functions normally can be calculated by the following formula:
LV_{DD}>(HV_{DD}−N·V_{THN})/3 (1)

For the above formula (1), if it is assumed that HV_{DD}=3.6 V, and V_{THN}=0.6 V, in the case of N=1, LV_{DD}>1V is satisfied. The second-stage level shifter operates with an adequate margin. Therefore, as the entire level-shift circuit, the level of an input signal input from the circuit of 1 V can be shifted to the level that can be applied to the circuit of 3.6 V such that the shift ratio is 3.6. Likewise, in the case of N=2, the formula becomes V_{DD}>0.8 V such that the shift ratio is 4.5. Also, in the case of N=3, the formula becomes LV_{DD}>0.6 V such that the shift ratio is 6. In this case, it is desired that the threshold voltages of the transistors QN11, QN12, QN21, and QN22 should be smaller than that of the transistor QN1.

A second embodiment of the invention will be described.

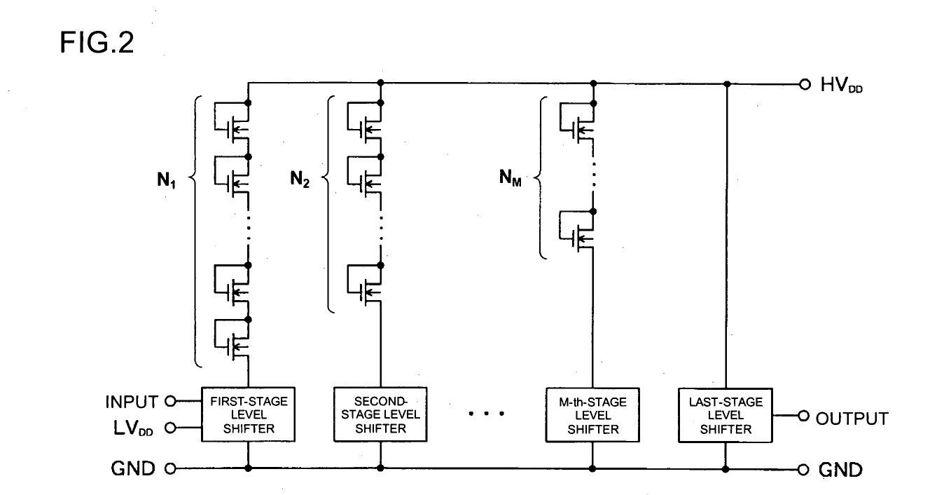

FIG. 2 is a schematic diagram showing a structure of a level-shift circuit included in a semiconductor integrated circuit according to a second embodiment of the invention. This semiconductor integrated circuit operates by the provision of the first power supply voltage LV_{DD} and the second power supply voltage HV_{DD} that is higher than the first one.

As shown in FIG. 2, this level-shift circuit comprises M level shifters (M is an integer) operated with the voltage supplied from the second power supply voltage HV_{DD} via at least one transistor and sequentially shift the level of a signal input from a circuit operated with the first power supply voltage LV_{DD}, and the last-stage level shifter operated with the second power supply voltage HV_{DD} and shifts the level of a signal input from the M-th-stage level shifter. The first-stage level shifter has the same configuration as that of the first-stage level shifter shown in FIG. 1, and each of the second-through last-stage level shifters has the same configuration as that of the second-stage level shifter shown in FIG. 1.

Between the second power supply voltage HV_{DD} and the first-stage level shifter, N₁ transistors are connected to each other in series to drop the second power supply voltage HV_{DD}. Between the second power supply voltage HV_{DD} and the second-stage level shifter, N₂ transistors are connected to each other in series. Like the above, between the second power supply voltage HV_{DD} and the M-th-stage level shifter, N_{M} transistors are connected to each other in series. Here, the following relationship is satisfied:
N₁>N₂> . . . >N_{M}.

In the embodiment, by selecting the combinations of (1) the number of the level shifters (M) and (2) the number of transistors (Nᵢ) that are connected to each other in series between the second power supply voltage HV_{DD} and the level shifter of each stage, level shift operation where the ratio of the level of the output signal to that of the input signal amounts to tens of times can be implemented rapidly.

For example, if the threshold voltage V_{THN} of the transistor is 0.8 V and the first and second power supply voltages LV_{DD} and HV_{DD} are 1.0 V and 3.3 V, respectively, assuming that the number of stages M=1, and the number of transistors N₁=1, the first-stage level shifter shifts voltage from 1.0 V to 2.5 V, and then the last-stage level shifter shifts it from 2.5 V to 3.3 V.

Meanwhile, when the first power supply voltage LV_{DD} is 1 V and the second power supply voltage HV_{DD} is 20 V, assuming that the number of stages M=2, and the numbers of transistors N₁=22 and N₂=16, the first-stage level shifter shifts voltage from 1 V to 2.4 V, the second-stage level shifter shifts it from 2.4 V to 7.2 V, and then the last-stage level shifter shifts it from 7.2 V to 20 V.

1. A semiconductor integrated circuit operated by a first power supply voltage and a second power supply voltage that is higher than the first power supply voltage, comprising:
at least one transistor that drops the second power supply voltage;
at least one level shifter operated with a voltage supplied from the second power supply voltage via the at least one transistor, and shifting a level of a signal input from a circuit that is operated with the first power supply voltage; and
a last-stage level shifter operated with the second power supply voltage and shifting a level of a signal that is input from the at least one level shifter.

2. The semiconductor integrated circuit according to claim 1, wherein the at least one transistor comprises a saturated-connected N-channel MOS transistor.

3. The semiconductor integrated circuit according to claim 1, wherein a threshold voltage of the at least one transistor is higher than a threshold voltage of any other transistors in the circuit.

4. The semiconductor integrated circuit according to claim 1, wherein:
the at least one level shifter comprises an i-th-stage level shifter (i=1, 2, . . . through M, with M being an integer) that is operated with a voltage supplied from the second power supply voltage via Nᵢ transistors; and
a relationship N₁>N₂> . . . >N_{M} is satisfied.

5. The semiconductor integrated circuit according to claim 1, wherein a first-stage level shifter of the at least one level shifter comprises:
an input inverter operated with the first power supply voltage and inverting a signal input from the circuit that is operated with the first power supply voltage;
a first inverter comprising a P-channel MOS transistor and an N-channel MOS transistor and inverting a signal input from the circuit that is operated with the first power supply voltage so as to produce a first output signal;
a second inverter comprising a P-channel MOS transistor and an N-channel MOS transistor and inverting a signal output from the input inverter so as to produce a second output signal;
a P-channel MOS transistor connected to the at least one transistor and the P-channel MOS transistor of the first inverter, and having a gate that receives the second output signal; and
a P-channel MOS transistor connected to the at least one transistor and the P-channel MOS transistor of the second inverter, and having a gate that receives the first output signal.

6. The semiconductor integrated circuit according to claim 1, wherein the second-stage and subsequent-stage level shifters, of the at least one level shifter, comprises:
a first inverter comprising a P-channel MOS transistor and an N-channel MOS transistor and inverting one of the output signals from a previous-stage level shifter so as to produce a first output signal;
a second inverter comprising a P-channel MOS transistor and an N-channel MOS transistor and inverting the other of the output signals from the previous-stage level shifter so as to produce a second output signal;
a P-channel MOS transistor connected to the at least one transistor and the P-channel MOS transistor of the first inverter, and having a gate that receives the second output signal; and
a P-channel MOS transistor connected to the at least one transistor and the P-channel MOS transistor of the second inverter, and having a gate that receives the first output signal.
